(19) United States
(12) Patent Application Publication
(10) Pub. No.: US 2022/0293439 A1
(43) Pub. Date: Sep. 15, 2022

(54) SUBSTRATE PROCESSING APPARATUS

(71) Applicant: Tokyo Electron Limited, Tokyo (JP)

(72) Inventors: Yuki WADA, Iwate (JP); Junnosuke TAGUCHI, Iwate (JP); Hisashi TAKAHASHI, Iwate (JP); Manabu HONMA, Iwate (JP)

(21) Appl. No.: 17/686,764

(22) Filed: Mar. 4, 2022

(30) Foreign Application Priority Data
Mar. 15, 2021 (JP) 2021-041636

(51) Int. Cl. H01L 21/67; H01L 21/687; H05B 3/00; F27B 17/00; F27D 5/00; F28F 13/00

(52) U.S. Cl. CPC H01L 21/67115; H01L 21/68771; H05B 3/0047; F27B 17/0025; F27D 5/0037; F28F 13/00; H05B 2203/032

(57) ABSTRACT

A substrate processing apparatus includes: a rotary table provided in a processing container; a stage provided on the rotary table to place a substrate thereon, and configured to revolve by a rotation of the rotary table; a heater configured to heat the substrate placed on the stage; and a rotation shaft configured to rotate together with the rotary table and support the stage to be rotatable; and a deflector configured to deflect heating light emitted from the heater toward the rotation shaft.

### CROSS-REFERENCE TO RELATED APPLICATIONS

This application is based on and claims priority from Japanese Patent Application No. 2021-041636, filed on Mar. 15, 2021, with the Japan Patent Office, the disclosure of which is incorporated herein in its entirety by reference.

### TECHNICAL FIELD

The present disclosure relates to a substrate processing apparatus.

### BACKGROUND

An apparatus is known which rotates a rotary table with a plurality of wafers placed thereon to revolve each wafer, and allows the wafers to repeatedly pass through processing gas supply regions arranged along the radial direction of the rotary table, thereby forming various types of films on the wafers (see, e.g., Japanese Patent Laid-Open Publication No. 2020-119921). In this apparatus, while the wafer is revolved by the rotary table, a stage of the wafer is rotated such that the wafer rotates, thereby improving the uniformity of a film in the circumferential direction of the wafer.

### SUMMARY

According to an aspect of the present disclosure, a substrate processing apparatus includes: a rotary table provided in a processing container; a stage provided on the rotary table to place a substrate thereon, and configured to revolve by a rotation of the rotary table; a heater configured to heat the substrate placed on the stage; and a rotation shaft configured to rotate together with the rotary table and support the stage to be rotatable; and a deflector configured to deflect heating light emitted from the heater toward the rotation shaft.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating an example of a configuration of a film forming apparatus according to an embodiment.

FIG. 2 is a plan view illustrating an internal configuration of a vacuum container of the film forming apparatus of FIG. 1.

FIG. 3 is a perspective view illustrating a configuration of a rotary table and a stage of the film forming apparatus of FIG. 1.

FIG. 4 is a cross-sectional view illustrating an internal configuration of an accommodation box of the film forming apparatus of FIG. 1.

FIGS. 5A and 5B are views illustrating an example of a mechanism that fixes the stage.

FIG. 6 is a view illustrating an example of a mechanism that fixes the rotary table.

FIGS. 7A and 7B are plan views illustrating an example of a first configuration of a deflector.

FIG. 8 is a cross-sectional view illustrating the example of the first configuration of the deflector.

FIGS. 9A to 9C are views illustrating an installation structure of a reflector.

FIGS. 10A to 10F are views illustrating a divided structure of the reflector.

FIGS. 11A to 11C are views (1) illustrating a cross-sectional shape of the reflector.

FIGS. 12A to 12C are views (2) illustrating the cross-sectional shape of the reflector.

FIG. 13 is a view (3) illustrating the cross-sectional shape of the reflector.

FIGS. 14A and 14B are views (4) illustrating the cross-sectional shape of the reflector.

FIGS. 15A to 15C are views (5) illustrating the cross-sectional shape of the reflector.

FIG. 16 is a view (1) illustrating a directivity of a heating light emitted from a heating element.

FIG. 17 is a view (2) illustrating the directivity of the heating light emitted from the heating element.

FIG. 18 is a view (3) illustrating the directivity of the heating light emitted from the heating element.

FIG. 19 is a cross-sectional view illustrating an example of a second configuration of the deflector.

FIG. 20 is a cross-sectional view illustrating an example of a third configuration of the deflector.

FIG. 21 is a cross-sectional view illustrating an example of a fourth configuration of the deflector.

FIG. 22 is a view illustrating measurement results of an in-plane distribution of a substrate temperature in Examples.

FIG. 23 is a graph obtained by normalizing the measurement results of FIG. 22.

FIG. 24 is a view illustrating measurement results of an in-plane distribution of a substrate temperature in Comparative Examples.

FIG. 25 is a graph obtained by normalizing the measurement results of FIG. 24.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, a non-limiting embodiment of the present disclosure will be described with reference to the accompanying drawings. In all of the drawings, the same or corresponding members or parts will be denoted by the same or corresponding reference numerals, and overlapping descriptions thereof will be omitted.

[Substrate Processing Apparatus]

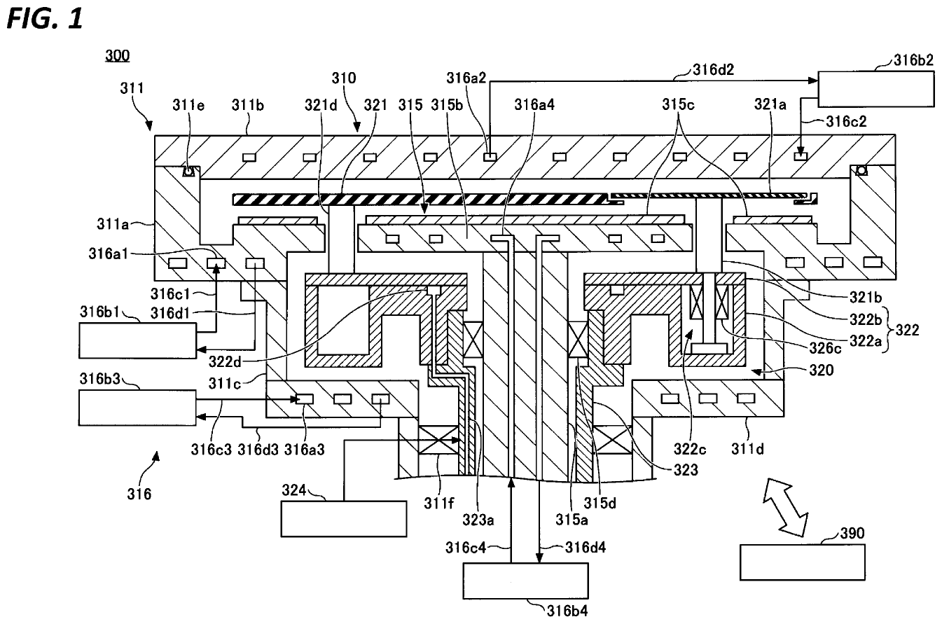

With reference to FIGS. 1 to 4, a film forming apparatus 300 that forms a film on a substrate will be described as an example of a substrate processing apparatus.

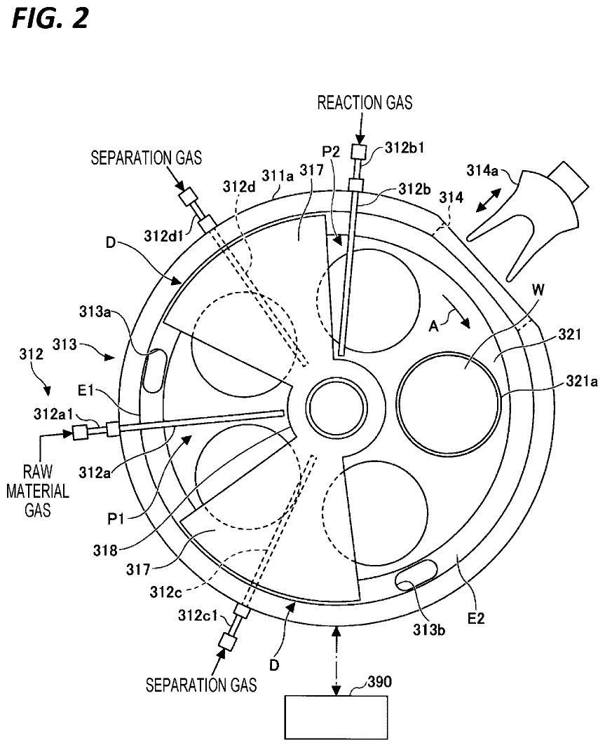

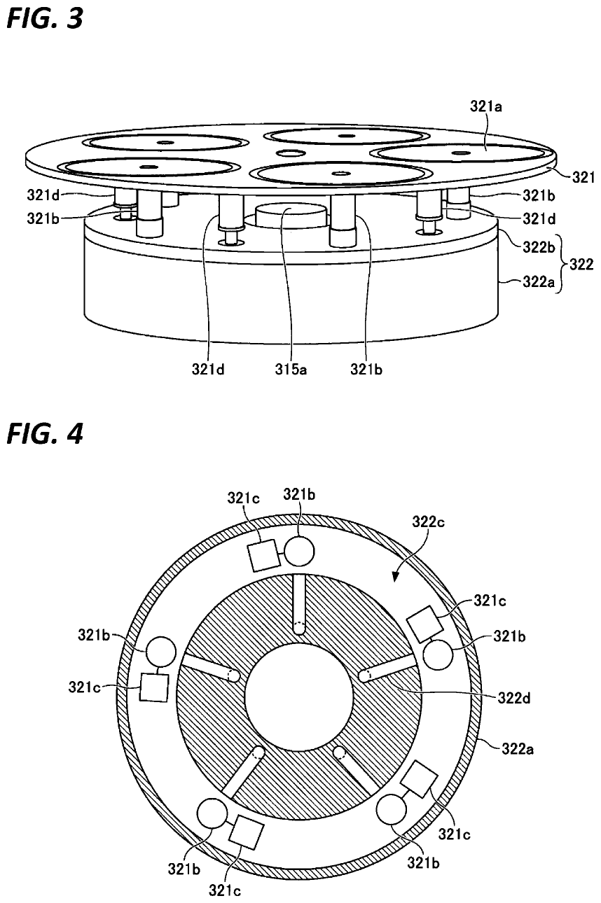

FIG. 1 is a cross-sectional view illustrating an example of a configuration of a film forming apparatus according to an embodiment. FIG. 2 is a plan view illustrating an internal configuration of a vacuum container of the film forming apparatus of FIG. 1. For the convenience of descriptions, FIG. 2 omits the illustration of a ceiling plate. FIG. 3 is a perspective view illustrating a configuration of a rotary table and a stage of the film forming apparatus of FIG. 1. FIG. 4 is a cross-sectional view illustrating an internal configuration of an accommodation box of the film forming apparatus of FIG. 1.

The film forming apparatus 300 includes a processing unit 310, a rotation driving device 320, and a controller 390.

The processing unit 310 is configured to execute a film forming process for forming a film on a substrate. The processing unit 310 includes a vacuum container 311, a gas introduction port 312, a gas exhaust port 313, a transfer port 314, a heating unit 315, and a cooling unit 316.

The vacuum container 311 is a processing container of which internal pressure may be reduced. The vacuum container 311 has a flat shape with a substantially circular planar shape, and accommodates a plurality of substrates W therein. The substrates W may be, for example, semiconductor wafers. The vacuum container 311 includes a main body 311a, a ceiling plate 311b, a side wall body 311c, and a bottom plate 311d (FIG. 1). The main body 311a has a cylindrical shape. The ceiling plate 311b is airtightly and detachably disposed on the upper surface of the main body 311a via a seal 311e. The side wall body 311c is connected to the lower surface of the main body 311a, and has a cylindrical shape. The bottom plate 311d is airtightly disposed on the bottom surface of the side wall body 311c.

The gas introduction port 312 includes a raw material gas nozzle 312a, a reaction gas nozzle 312b, and separation gas nozzles 312c and 312d (FIG. 2). The raw material gas nozzle 312a, the reaction gas nozzle 312b, and the separation gas nozzles 312c and 312d are arranged above a rotary table 321 in the circumferential direction of the vacuum container 311 (the direction indicated by the arrow A in FIG. 2) at intervals. In the illustrated example, the separation gas nozzle 312c, the raw material gas nozzle 312a, the separation gas nozzle 312d, and the reaction gas nozzle 312b are arranged in this order in the clockwise direction (the rotation direction of the rotary table 321) from the transfer port 314. Gas introduction ports 312a1, 312b1, 312c1, and 312d1 (FIG. 2), which are the base ends of the raw material gas nozzle 312a, the reaction gas nozzle 312b, and the separation gas nozzles 312c and 312d, are fixed to the outer wall of the main body 311a. Then, the raw material gas nozzle 312a, the reaction gas nozzle 312b, and the separation gas nozzles 312c and 312d are introduced into the vacuum container 311 from the outer wall of the vacuum container 311, and attached to extend horizontally with respect to the rotary table 321 along the radial direction of the main body 311a. The raw material gas nozzle 312a, the reaction gas nozzle 312b, and the separation gas nozzles 312c and 312d are formed of, for example, quartz.

The raw material gas nozzle 312a is connected to a supply source (not illustrated) of a raw material gas via, for example, a pipe and a flow rate controller (not illustrated). As for the raw material gas, for example, a silicon-containing gas and a metal-containing gas may be used. In the raw material gas nozzle 312a, a plurality of ejection holes (not illustrated) is formed to be opened toward the rotary table 321, and arranged at intervals along the length direction of the raw material gas nozzle 312a. The region under the raw material gas nozzle 312a becomes a raw material gas adsorption region P1 where the raw material gas is adsorbed to a substrate W.

The reaction gas nozzle 312b is connected to a supply source (not illustrated) of a reaction gas via, for example, a pipe and a flow rate controller (not illustrated). As for the reaction gas, for example, an oxidizing gas or a nitriding gas may be used. In the reaction gas nozzle 312b, a plurality of ejection holes (not illustrated) is formed to be opened toward the rotary table 321, and arranged at intervals along the length direction of the reaction gas nozzle 312b. The region under the reaction gas nozzle 312b becomes a reaction gas supply region P2 where the raw material gas adsorbed onto the substrate W in the raw material gas adsorption region P1 is oxidized or nitrided.

The separation gas nozzles 312c and 312d are both connected to a supply source (not illustrated) of a separation gas via, for example, pipes and flow rate control valves (not illustrated). As for the separation gas, for example, an inert gas such as argon (Ar) gas or nitrogen (N₂) gas may be used. In each of the separation gas nozzles 312c and 312d, a plurality of ejection holes (not illustrated) is formed to be opened toward the rotary table 321, and arranged at intervals along the length direction of each of the separation gas nozzles 312c and 312d.

As illustrated in FIG. 2, two convex portions 317 are formed in the vacuum container 311. The convex portions 317 are attached to the back surface of the ceiling plate 311b to project toward the rotary table 2, in order to make up separation regions D together with the separation gas nozzles 312c and 312d. Each convex portion 317 has a fan planar shape cut in an arc shape at the top portion thereof, and is disposed such that the inner arc is connected to a protrusion 318, and the outer arc follows the inner wall of the main body 311a of the vacuum container 311.

The gas exhaust port 313 includes a first exhaust port 313a and a second exhaust port 313b (FIG. 2). The first exhaust port 313a is formed at the bottom of a first exhaust region E1 that communicates with the raw material gas adsorption region P1. The second exhaust port 313b is formed at the bottom of a second exhaust region E2 that communicates with the reaction gas supply region P2. The first exhaust port 313a and the second exhaust port 313b are connected to an exhaust device (not illustrated) via exhaust pipes (not illustrated).

The transfer port 314 is formed in the side wall of the vacuum container 311 (FIG. 2). Through the transfer port 314, the substrate W is transferred between the rotary table 321 inside the vacuum container 311 and a transfer arm 314a outside the vacuum container 311. The transfer port 314 is opened and closed by a gate valve (not illustrated).

The heating unit 315 includes a fixed shaft 315a, a heater support 315b, and a heater 315c (FIG. 1).

The fixed shaft 315a has a cylindrical shape of which central axis is the center of the vacuum container 311. The fixed shaft 315a is provided inside a rotary shaft 323 to penetrate the bottom plate 311d of the vacuum container 311. A seal 315d is provided between the outer wall of the fixed shaft 315a and the inner wall of the rotary shaft 323. Accordingly, the rotary shaft 323 rotates around the fixed shaft 315a while maintaining the airtight state inside the vacuum container 311. The seal 315d includes, for example, a magnetic fluid seal.

The heater support 315b is fixed to the upper portion of the fixed shaft 315a, and has a disc shape. The heater support 315b supports the heater 315c.

The heater 315c is provided on the upper surface of the heater support 315b. The heater 315c may be provided on the main body 311a, in addition to the upper surface of the heater support 315b. The heater 315c includes a heating element that generates heat when an electric power is supplied from a power source (not illustrated), and the substrate W is heated by a heating light emitted by the heating element. A portion of the heating light emitted from the heating element is deflected toward a rotation shaft 321b by a deflector. The deflector and the rotation shaft 321b will be described later.

The cooling unit 316 includes fluid flow paths 316a1 to 316a4, chiller units 316b1 to 316b4, inlet pipes 316c1 to 316c4, and outlet pipes 316d1 to 316d4. The fluid flow paths 316a1 to 316a4 are formed inside the main body 311a, the ceiling plate 311b, the bottom plate 311d, and the heater support 315b, respectively. The chiller units 316b1 to 316b4 output temperature control fluids. The temperature adjustment fluids output from the chiller units 316b1 to 316b4 circulate by flowing through the inlet pipes 316c1 to 316c4, the fluid flow paths 316a1 to 316a4, and the outlet pipes 316d1 to 316d4 in this order. Accordingly, the temperatures of the main body 311a, the ceiling plate 311b, the bottom plate 311d, and the heater support 315b are adjusted. As for the temperature adjustment fluids, for example, water or a fluorine-based fluid such as Galden (registered trademark) may be used.

The rotation driving device 320 includes the rotary table 321, an accommodation box 322, the rotary shaft 323, and a revolution motor 324.

The rotary table 321 is provided inside the vacuum container 311, and has the rotation axis at the center of the vacuum container 311. The rotary table 321 has, for example, a disc shape and is formed of quartz. A plurality of (e.g., five) stages 321a is provided on the upper surface of the rotary table 321 along the rotation direction (circumferential direction) of the rotary table 321. The rotary table 321 is connected to the accommodation box 322 via a connector 321d.

Each stage 321a has a disc shape slightly larger than the substrate W, and is formed of, for example, quartz. The substrate W is placed on each stage 321a. The substrate W may be, for example, a semiconductor wafer. Each stage 321a is connected to a rotation motor 321c via the rotation shaft 321b, and configured to be rotatable with respect to the rotary table 321.

The rotation shaft 321b connects the lower surface of the stage 321a and the rotation motor 321c accommodated inside the accommodation box 322 to each other, and transmits the power of the rotation motor 321c to the stage 321a. The rotation shaft 321b is configured to be rotatable using the center of the stage 321a as the rotation axis thereof. The rotation shaft 321b is provided to penetrate the ceiling 322b of the accommodation box 322 and the rotary table 321. A seal 326c is provided in the through hole of the ceiling 322b of the accommodation box 322, so that the airtight state inside the accommodation box 322 is maintained. The seal 326c includes, for example, a magnetic fluid seal.

The rotation motor 321c rotates the stage 321a with respect to the rotary table 321 via the rotation shaft 321b, so as to rotate the substrate. The rotation motor 321c may be, for example, a servomotor.

The connector 321d connects, for example, the lower surface of the rotary table 321 and the upper surface of the accommodation box 322 to each other. A plurality of connectors 321d is provided along, for example, the circumferential direction of the rotary table 321.

The detailed structures of the rotary table 321, the stage 321a, the rotation shaft 321b, and the connector 321d will be described later.

The accommodation box 322 is provided below the rotary table 321 inside the vacuum container 311. The accommodation box 322 is connected to the rotary table 321 via the connector 321d, and configured to be rotatable integrally with the rotary table 321. The accommodation box 322 may be configured to be movable up and down in the vacuum container 311 by a lifting mechanism (not illustrated). The accommodation box 322 includes a main body 322a and a ceiling 322b.

The main body 322a is formed in a concave shape in the cross-sectional view, and formed in a ring shape along the rotation direction of the rotary table 321.

The ceiling 322b is provided on the upper surface of the main body 322a to cover the opening of the main body 322a formed in the concave shape in the cross-sectional view. Accordingly, the main body 322a and the ceiling 322b form an accommodation portion 322c isolated from the inside of the vacuum container 311.

The accommodation portion 322c is formed in a rectangular shape in the cross-sectional view, and formed in a ring shape along the rotation direction of the rotary table 321. The accommodation portion 322c accommodates the rotation motor 321c. In the main body 322a, a communication passage 322d is formed to communicate the accommodation portion 322c and the outside of the film forming apparatus 300 with each other. Accordingly, the atmosphere is introduced into the accommodation portion 322c from the outside of the film forming apparatus 300, so that the inside of the accommodation portion 322c is cooled and maintained at the atmospheric pressure.

The rotary shaft 323 is fixed to the lower portion of the accommodation box 322. The rotary shaft 323 is provided to penetrate the bottom plate 311d of the vacuum container 311. The rotary shaft 323 transmits the power of the revolution motor 324 to the rotary table 321 and the accommodation box 322, to rotate the rotary table 321 and the accommodation box 322 integrally. A seal 311f is provided in the through hole of the bottom plate 311d of the vacuum container 311, so that the airtight state inside the vacuum container 311 is maintained. The seal 311f includes, for example, a magnetic fluid seal.

A through hole 323a is formed inside the rotary shaft 323. The through hole 323a is connected to the communication passage 322d of the accommodation box 322, and functions as a fluid flow path for introducing the atmosphere into the accommodation box 322. The through hole 323a also functions as a wiring duct for introducing a power line and a signal line for driving the rotation motor 321c in the accommodation box 322. The through hole 323a is formed as many as the number of, for example, the rotation motors 321c.

The controller 390 controls each unit of the film forming apparatus 300. The controller 390 may be, for example, a computer. A storage medium stores a computer program for performing the operation of each unit of the film forming apparatus 300. The storage medium may be, for example, a flexible disc, a compact disc, a hard disc, a flash memory, or a DVD.

[Fixing Mechanism of Stage]

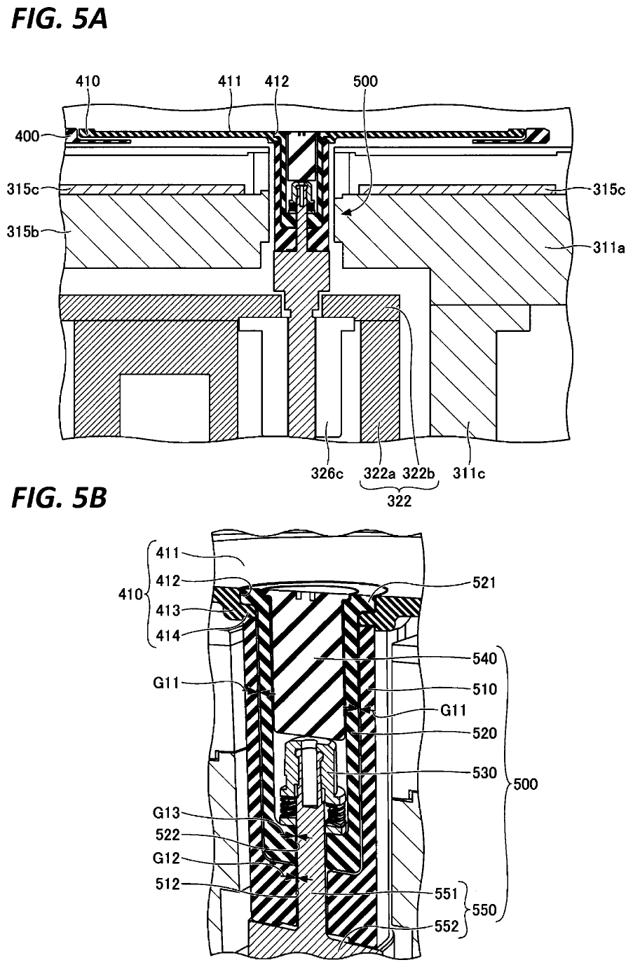

With reference to FIGS. 5A and 5B, an example of a mechanism that fixes the stage 321a in the above-described film forming apparatus 300 will be described. FIGS. 5A and 5B are views illustrating an example of the mechanism that fixes the stage. FIG. 5A is a cross-sectional view illustrating a positional relationship between the stage and clamps, and FIG. 5B is an enlarged view of the clamps of FIG. 5A.

First, an example of a configuration of the stage 321a will be described. Hereinafter, a rotary table 400 and a stage 410 will be described as the rotary table 321 and the stage 321a, respectively.

The stage 410 has a rotation center at a position spaced from the rotation center of the rotary table 400, and is configured to be rotatable with respect to the rotary table 400. Hereinafter, the rotation center of the rotary table 400 will also be referred to as a revolution center, and the rotation center of the stage 410 will be referred to as a rotation center. The revolution center and the rotation center are spaced from each other by, for example, 300 mm to 400 mm Thus, when the rotary table 400 rotates, a centrifugal force acts on the stage 410. In particular, when the rotary table 400 rotates at a high speed (e.g., 200 rpm or more), a large centrifugal force acts on the stage 410.

The stage 410 is formed of, for example, a material having a relatively high heat conductivity, such as Al₂O₃, AlN, or SiC. The stage 410 includes a placing portion 411, an opening 412, a thickness portion 413, and a flange portion 414.

The placing portion 411 is a recess formed in the upper surface of the stage 410. The placing portion 411 has an outer diameter slightly larger than that of the substrate W, and has substantially the same depth as that of the substrate W. The substrate W is placed on the placing portion 411.

The opening 412 is formed at the rotation center of the stage 410. In other words, the opening 412 is formed at the position spaced from the rotation center of the rotary table 400. The opening 412 has, for example, a circular shape.

The thickness portion 413 is a portion that extends downward from the lower surface of the stage 410 around the opening 412 of the stage 410, and has an annular shape.

The flange portion 414 is a portion that protrudes from the inner wall of the thickness portion 413 toward the center of the opening 412, and has an annular shape. The upper surface of the flange portion 414 is disposed below the upper surface of the placing portion 411 of the stage 410.

The fixing mechanism 500 includes a first clamp 510, a second clamp 520, a pressing member 530, a lid 540, and a shaft 550. The first clamp 510, the second clamp 520, the pressing member 530, the lid 540, and the shaft 550 function as the rotation shaft 321b described above.

The first clamp 510 has a bottomed cylindrical shape, and is configured such that the upper end of the cylindrical shape comes into contact with the lower surface of the flange portion 414 of the stage 410. At the bottom of the first clamp 510, a first through hole 512 is formed such that an insertion portion 551 of the shaft 550 may be inserted through the first through hole 512. The first through hole 512 has an inner diameter slightly (e.g., 0.1 mm to 5.0 mm) larger than the outer diameter of the insertion portion 551. The first clamp 510 is formed of a material having a heat resistant temperature higher than the temperature of the film forming process (e.g., 600° C.) performed in the film forming apparatus 300 and having a heat conductivity lower than that of the stage 410. For example, when the stage 410 is formed of Al₂O₃, AlN, or SiC, the first clamp 510 is formed of, for example, quartz. Further, the first clamp 510 may be formed of a material having a heat conductivity 10 or more times lower than that of the stage 410.

The second clamp 520 is provided inside the first clamp 510 with a gap G11 from the inner wall of the first clamp 510. The gap G11 may be, for example, 0.1 mm to 5.0 mm. The second clamp 520 has a bottomed cylindrical shape with an outer diameter smaller than the inner diameter of the first clamp 510. The second clamp 520 includes a contact portion 521. The contact portion 521 has an annular shape that extends outward from the outer wall of the upper end of the second clamp 520, and comes into contact with the upper surface of the flange portion 414 formed on the stage 410. At the bottom of the second clamp 520, a second through hole 522 is formed such that the insertion portion 551 of the shaft 550 may be inserted through the second through hole 522. The second through hole 522 has an inner diameter slightly (e.g., 0.1 mm to 5.0 mm) larger than the outer diameter of the insertion portion 551. The second clamp 520 is formed of a material having a heat resistant temperature higher than the temperature of the film forming process (e.g., 600° C.) performed in the film forming apparatus 300 and having a heat conductivity lower than that of the stage 410. For example, when the stage 410 is formed of Al₂O₃, AlN, or SiC, the second clamp 520 is formed of, for example, quartz. Further, the second clamp 520 may be formed of a material having a heat conductivity 10 or more times lower than that of the stage 410. The second clamp 520 may be formed of the same material as that of the first clamp 510, from the viewpoint of suppressing an occurrence of a difference in thermal expansion.

In this way, the upper end of the first clamp 510 comes into contact with the lower surface of the flange portion 414, and the contact portion 521 of the second clamp 520 comes into contact with the upper surface of the flange portion 414, so that the flange portion 414 is sandwiched between the first clamp 510 and the second clamp 520.

The pressing member 530 presses the first clamp 510 and the second clamp 520 in the direction in which the first and second clamps 510 and 520 approach each other. For example, the pressing member 530 is disposed on the inside bottom surface of the second clamp 520, and presses the bottom of the second clamp 520 toward the bottom of the first clamp 510. Accordingly, the flange portion 414 is sandwiched between the upper end of the first clamp 510 and the contact portion 521 of the second clamp 520, and fixed by the pressing force of the pressing member 530. As a result, the centrifugal force generated when the rotary table 400 rotates suppresses, for example, the stage 410 and the second clamp 520 from falling toward the outer periphery of the rotary table 400. The pressing member 530 includes, for example, a disc spring.

The lid 540 has a columnar shape having substantially the same outer diameter as the inner diameter of the second clamp 520, and is inserted into the second clamp 520 to close the upper opening of the second clamp 520. Accordingly, the pressing member 530 is suppressed from being exposed to the raw material gas or the reaction gas. Thus, even when the pressing member 530 is formed of a metal material, the corrosion of the pressing member 530 may be suppressed. The lid 540 may be formed of a material having a heat resistant temperature higher than the temperature of the film forming process (e.g., 600° C.) performed in the film forming apparatus 300 and having a heat absorption rate higher than that of the stage 410. For example, when the stage 410 is formed of Al₂O₃, the lid 540 may be formed of, for example, SiC or carbon (C).

The shaft 550 is formed of, for example, a metal material, and includes an insertion portion 551 and a penetration portion 552.

The insertion portion 551 is the upper portion of the shaft 550. The insertion portion 551 penetrates the first through hole 512 and the second through hole 522, such that the upper end thereof is fixed by the pressing member 530 inside the second clamp 520. Since the outer diameter of the insertion portion 551 is slightly larger than the inner diameter of the first through hole 512, a gap G12 is formed between the outer wall of the insertion portion 551 and the inner wall of the first through hole 512. Further, since the outer diameter of the insertion portion 551 is slightly larger than the inner diameter of the second through hole 522, a gap G13 is formed between the outer wall of the insertion portion 551 and the inner wall of the second through hole 522.

The penetration portion 552 is the lower portion of the shaft 550. The penetration portion 552 is provided to penetrate the ceiling 322b of the accommodation box 322. The lower end of the penetration portion 552 is disposed inside the accommodation box 322. The penetration portion 552 transmits the power of the rotation motor 321c (FIG. 4) disposed inside the accommodation box 322 to the stage 410 via the first clamp 510 and the second clamp 520. In other words, when the penetration portion 552 rotates by the power of the rotation motor 321c, the first clamp 510, the second clamp 520, and the stage 410 rotate. The insertion portion 551 and the penetration portion 552 may be formed as separate bodies.

According to the fixing mechanism 500 described above, the stage 410 is inserted between the first clamp 510 and the second clamp 520, and fixed in the manner that the pressing member 530 presses the first clamp 510 and the second clamp 520 in the direction in which the first and second clamps 510 and 520 approach each other. Accordingly, the difference in thermal expansion may be absorbed in a state where the rotation center is aligned. As a result, the damage of, for example, the stage 410 and the fixing mechanism 500 caused from a thermal stress may be suppressed.

Further, according to the fixing mechanism 500, the gaps G12 and G13 are formed between the insertion portion 551 and the first through hole 512 and between the insertion portion 551 and the second through hole 522. Thus, even when the difference in thermal expansion occurs between the insertion portion 551 and the first clamp 510 and between the insertion portion 551 and the second clamp 520, the generation of stress on, for example, the insertion portion 551, the first clamp 510, and the second claim 520 may be suppressed. As a result, the damage of, for example, the first clamp 510, the second clamp 520, and the stage 410 may be suppressed.

Further, according to the fixing mechanism 500, the shaft 550 is covered with the first clamp 510 and the second clamp 520, and fixed by the pressing force of the pressing member 530 disposed on the inside bottom surface of the second clamp 520. Accordingly, the shaft 550 is suppressed from being exposed to the raw material gas or the reaction gas. As a result, even when the shaft 550 is formed of a material corrosive to the raw material gas or the reaction gas, the corrosion of the shaft 550 may be suppressed.

Further, according to the fixing mechanism 500, the shaft 550 is provided to penetrate the ceiling 322b of the accommodation box 322, and the lower end of the shaft 550 disposed inside the accommodation box 322 becomes a portion connected to the rotation motor 321c. Accordingly, the rotation motor 321c may be disposed inside the accommodation box 322. As a result, the temperature rise of the rotation motor 321c may be suppressed.

[Fixing Mechanism of Rotary Table]

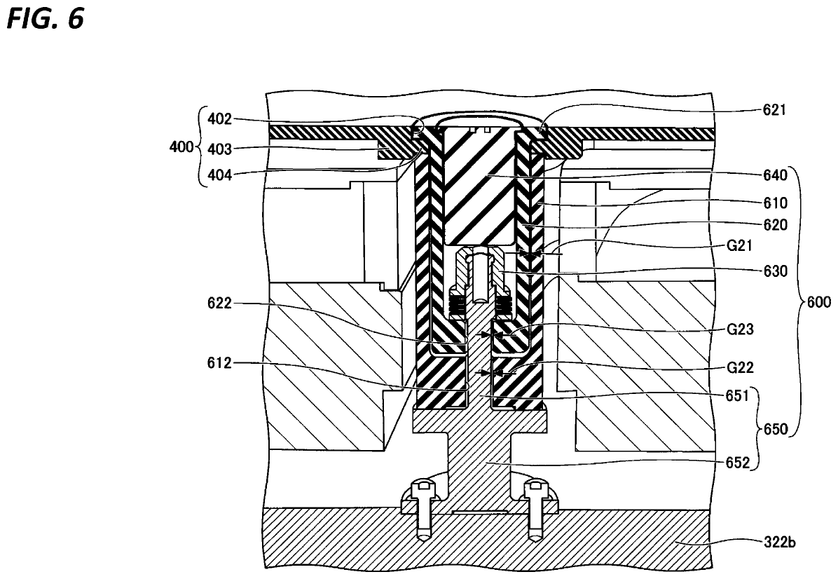

With reference to FIG. 6, an example of a mechanism that fixes the rotary table 321 in the above-described film forming apparatus 300 will be described. FIG. 6 is a view illustrating an example of the mechanism that fixes the rotary table.

First, an example of a configuration of the rotary table 321 will be described. Hereinafter, the rotary table 400 will be described as the rotary table 321.

The rotary table 400 is rotatably provided inside the vacuum container 311. The rotary table 400 includes an opening 402, a thickness portion 403, and a flange portion 404.

A plurality of openings 402 is formed along the circumferential direction of the rotary table 400, at positions spaced from the rotation center of the rotary table 400. Each opening 402 has, for example, a circular shape.

The thickness portion 403 is a portion that extends downward from the lower surface of the rotary table 400 around the opening 402 of the rotary table 400, and has an annular shape.

The flange portion 404 is a portion that protrudes from the inner wall of the thickness portion 403 toward the center of the opening 402, and has an annular shape. The upper surface of the flange portion 404 is disposed below the upper surface of the rotary table 400.

The fixing mechanism 600 includes a first clamp 610, a second clamp 620, a pressing member 630, a lid 640, and a shaft 650. The first clamp 610, the second clamp 620, the pressing member 630, the lid 640, and the shaft 650 function as the connector 321d described above.

The first clamp 610 has a bottomed cylindrical shape and is configured such that the upper end of the cylindrical shape comes into contact with the lower surface of the flange portion 404 of the rotary table 400. At the bottom of the first clamp 610, a first through hole 612 is formed such that an insertion portion 651 of the shaft 650 may be inserted through the first through hole 612. The first through hole 612 has an inner diameter slightly (e.g., 0.1 mm to 5.0 mm) larger than the outer diameter of the insertion portion 651. The first clamp 610 is formed of a material having a heat resistant temperature higher than the temperature of the film forming process (e.g., 600° C.) performed in the film forming apparatus 300, such as, for example, quartz or ceramics.

The second clamp 620 is provided inside the first clamp 610 with a gap G21 from the inner wall of the first clamp 610. The gap G21 may be, for example, 0.1 mm to 5.0 mm. The second clamp 620 has a bottomed cylindrical shape with an outer diameter smaller than the inner diameter of the first clamp 610. The second clamp 620 includes a contact portion 621. The contact portion 621 has an annular shape that extends outward from the outer wall of the upper end of the second clamp 620, and comes into contact with the upper surface of the flange portion 404 formed on the stage 410. At the bottom of the second clamp 620, a second through hole 622 is formed such that the insertion portion 651 of the shaft 650 may be inserted through the second through hole 622. The second through hole 622 has an inner diameter slightly (e.g., 0.1 mm to 5.0 mm) larger than the outer diameter of the insertion portion 651. The second clamp 620 is formed of a material having a heat resistant temperature higher than the temperature of the film forming process (e.g., 600° C.) performed in the film forming apparatus 300, such as, for example, quartz or ceramics. The second clamp 620 may be formed of the same material as that of the first clamp 610, from the viewpoint of suppressing the occurrence of a difference in thermal expansion.

In this way, the upper end of the first clamp 610 comes into contact with the lower surface of the flange portion 404, and the contact portion 621 of the second clamp 620 comes into contact with the upper surface of the flange portion 404, so that the flange portion 404 is sandwiched between the first clamp 610 and the second clamp 620.

The pressing member 630 presses the first clamp 610 and the second clamp 620 in the direction in which the first and second clamps 610 and 620 approach each other. For example, the pressing member 630 is disposed on the inside bottom surface of the second clamp 620, and presses the bottom of the second clamp 620 toward the bottom of the first clamp 610. Accordingly, the flange portion 404 is sandwiched between the upper end of the first clamp 610 and the contact portion 621 of the second clamp 620, and fixed by the pressing force of the pressing member 630. The pressing member 630 includes, for example, a disc spring.

The lid 640 has a columnar shape having substantially the same outer diameter as the inner diameter of the second clamp 620, and is inserted into the second clamp 620 to close the upper opening of the second clamp 620. Accordingly, the pressing member 630 is suppressed from being exposed to the raw material gas or the reaction gas. Thus, even when the pressing member 630 is formed of a metal material, the corrosion of the pressing member 630 may be suppressed. The lid 640 may be formed of a material having a heat resistant temperature higher than the temperature of the film forming process (e.g., 600° C.) performed in the film forming apparatus 300, such as, for example, quartz or ceramics.

The shaft 650 is formed of, for example, a metal material, and includes an insertion portion 651 and a support 652.

The insertion portion 651 is the upper portion of the shaft 650. The insertion portion 651 penetrates the first through hole 612 and the second through hole 622, such that the upper end thereof is fixed by the pressing member 630 inside the second clamp 620. Since the outer diameter of the insertion portion 651 is slightly larger than the inner diameter of the first through hole 612, a gap G22 is formed between the outer wall of the insertion portion 651 and the inner wall of the first through hole 612. Further, since the outer diameter of the insertion portion 651 is slightly larger than the inner diameter of the second through hole 622, a gap G23 is formed between the outer wall of the insertion portion 651 and the inner wall of the second through hole 622.

The support 652 is the lower portion of the shaft 650. The lower end of the support 652 is fixed to the upper surface of the ceiling 322b of the accommodation box 322. The insertion portion 651 and the support 652 may be formed as separate bodies.

According to the fixing mechanism 600 described above, the rotary table 400 is inserted between the first clamp 610 and the second clamp 620, and fixed in the manner that the pressing member 630 presses the first clamp 610 and the second clamp 620 in the direction in which the first and second clamps 610 and 620 approach each other. Accordingly, the difference in thermal expansion may be absorbed in a state where the revolution center is aligned. As a result, the damage of, for example, the rotary table 400 and the fixing mechanism 600 caused from the thermal stress may be suppressed.

Further, according to the fixing mechanism 600, the gaps G22 and G23 are formed between the insertion portion 651 and the first through hole 612 and between the insertion portion 651 and the second through hole 622. Thus, even when a difference in thermal expansion occurs between the insertion portion 651 and the first clamp 610 and between the insertion portion 651 and the second clamp 620, the generation of stress on, for example, the insertion portion 651, the first clamp 610, and the second clamp 620 may be suppressed. As a result, the damage of, for example, the first clamp 610, the second clamp 620, and the rotary table 400 may be suppressed.

Further, according to the fixing mechanism 600, the shaft 650 is covered with the first clamp 610 and the second clamp 620, and fixed by the pressing force of the pressing member 630 disposed on the inside bottom surface of the second clamp 620. Accordingly, the shaft 650 is suppressed from being exposed to the raw material gas or the reaction gas. As a result, even when the shaft 650 is formed of a material corrosive to the raw material gas or the reaction gas, the corrosion of the shaft 650 may be suppressed.

[Deflector]

### Example of First Configuration

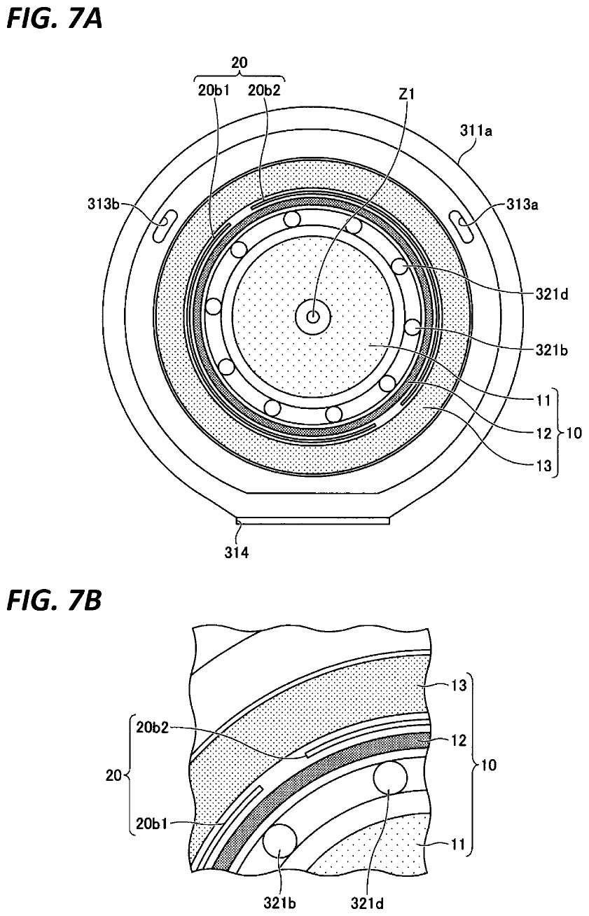

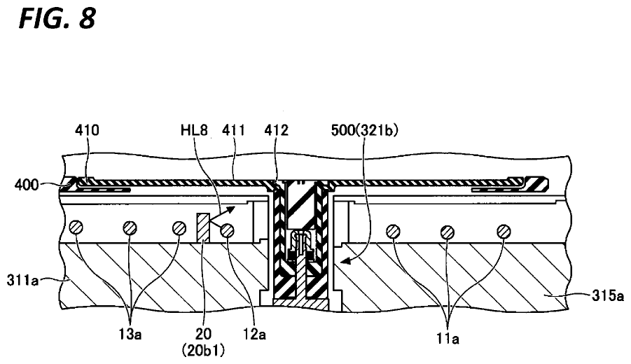

With reference to FIGS. 7A, 7B, and 8, an example of a first configuration of the deflector provided in the film forming apparatus 300 as described above will be described. The deflector according to the example of the first configuration includes a reflector 20 that reflects a heating light emitted from the heating element of the heater 315c toward the rotation shaft 321b. Hereinafter, a heater 10 will be described as the heater 315c.

The heater 10 includes an inner heater 11, an intermediate heater 12, and an outer heater 13. The inner heater 11, the intermediate heater 12, and the outer heater 13 are configured to be controllable independently from each other. The heater 10 may include only one heater, or may include two or four or more independently controllable heaters.

The inner heater 11 includes a heating element 11a. The heating element 11a is provided below the rotary table 400 along the circumferential direction of the rotary table 400. The heating element 11a is provided closer to the rotation center Z1 of the rotary table 400 than the position where the rotation shaft 321b is provided. The heating element 11a is enclosed in, for example, a quartz tube.

The intermediate heater 12 includes a heating element 12a. The heating element 12a is provided below the rotary table 400 along the circumferential direction of the rotary table 400. The heating element 12a is provided closer to the outer periphery of the rotary table 400 than the position where the rotation shaft 321b is provided. The heating element 12a is enclosed in, for example, a quartz tube.

The outer heater 13 includes a heating element 13a. The heating element 13a is provided below the rotary table 400 along the circumferential direction of the rotary table 400. The heating element 13a is provided closer to the outer periphery of the rotary table 400 than the position where the heating element 12a is provided. The heating element 13a is enclosed in, for example, a quartz tube.

The reflector 20 reflects heating light HL8 emitted from the heating element 12a of the intermediate heater 12 toward the outer periphery of the rotary table 400, toward the rotation shaft 321b. The reflector 20 extends in the circumferential direction of the rotary table 400. For example, as illustrated in FIGS. 7A and 7B, the reflector 20 includes two reflection blocks 20b1 and 20b2. Each of the reflection blocks 20b1 and 20b2 has an arc shape in the plan view. As illustrated in FIG. 8, each of the reflection block 20b1 and 20b2 has a rectangular shape in the cross-sectional view along the radial direction of the rotary table 400. The material of each of the reflection blocks 20a1 and 20b2 may be a metal such as aluminum (Al), from the viewpoint of obtaining a high reflectivity. The material of each of the reflection blocks 20b1 and 20b2 may be ceramics such as, for example, aluminum oxide (Al₂O₃).

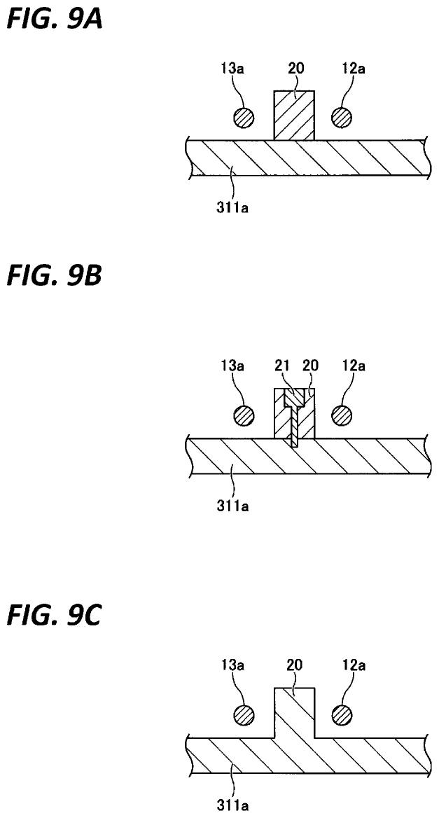

Next, the installation structure of the reflector 20 will be described with reference to FIGS. 9A to 9C.

As illustrated in FIG. 9A, the reflector 20 may be configured as a separate component from, for example, the main body 311a, and may be mounted on the main body 311a without being fixed thereto. As a result, even when a difference in thermal expansion occurs between the reflector 20 and the main body 311a due to the change in temperature of the film forming process, the deformation of, for example, the reflector 20 and the main body 311a may be suppressed. Further, since the number of reflectors 20 mounted may easily be changed according to the temperature zone of the film forming process, the required directivity may be selected according to the temperature zone of the film forming process.

As illustrated in FIG. 9B, the reflector 20 may be configured as a separate component from, for example, the main body 311a, and may be fixed onto the main body 311a with a fixing member 21 such as, for example, a screw. As a result, the reflector 20 is reliably in contact with the main body 311a cooled by the cooling unit 316. Thus, the thermal resistance between the reflector 20 and the main body 311a decreases, and heat is easily dissipated from the reflector 20 to the main body 311a. As a result, the rise of the temperature of the reflector 20 is suppressed.

As illustrated in FIG. 9C, the reflector 20 may be formed integrally with the main body 311a. As a result, the reflector 20 is directly cooled by the cooling unit 316, so that the rise of the temperature of the reflector 20 is suppressed.

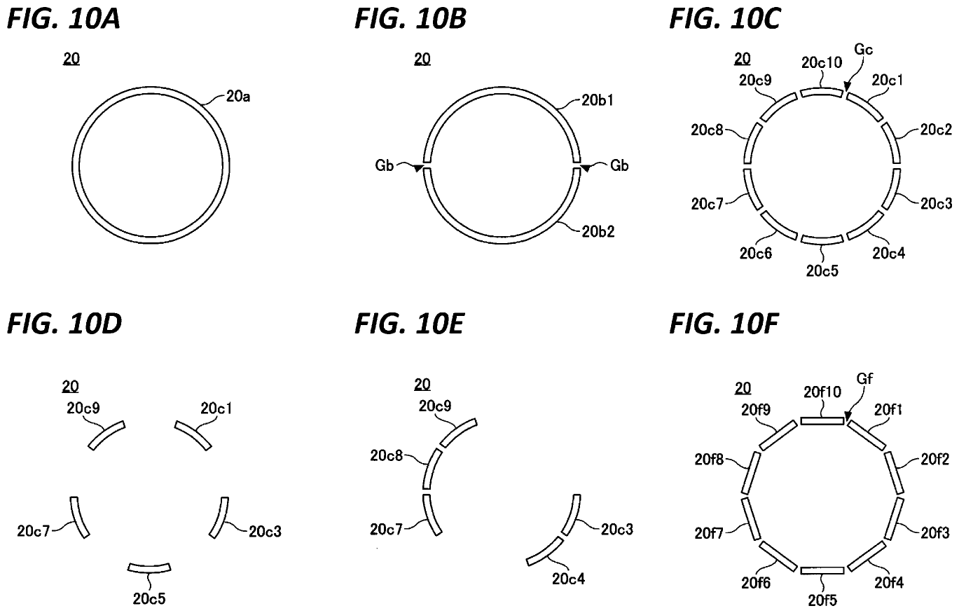

Next, the divided structure of the reflector 20 will be described with reference to FIGS. 10A to 10F. FIGS. 10A to 10F are views when the reflector 20 is viewed from above.

As illustrated in FIG. 10A, the reflector 20 may include one cylindrical reflection block 20a that extends in the circumferential direction of the rotary table 400.

As illustrated in FIG. 10B, the reflector 20 may include the reflection blocks 20b1 and 20b2 formed by dividing the cylindrical reflection block 20a into two parts. Each of the reflection blocks 20b1 and 20b2 extends in the circumferential direction of the rotary table 400, and has a semi-circular arc shape in the plan view. The reflection blocks 20b1 and 20b2 are provided with a gap Gb between the adjacent reflection blocks 20b1 and 20b2. However, the reflection blocks 20b1 and 20b2 may be provided with no gap Gb between the adjacent reflection blocks 20b1 and 20b2.

As illustrated in FIG. 10C, the reflector 20 may include reflection blocks 20c1 to 20c10 formed by dividing the cylindrical reflection block 20a into ten parts. Each of the reflection blocks 20c1 to 20c10 extends in the circumferential direction of the rotary table 400, and has an arc shape in the plan view. The reflection blocks 20c1 to 20c10 are provided with a gap Gc between adjacent reflection blocks among the reflection blocks 20c1 to 20c10. However, the reflection blocks 20c1 to 20c10 may be provided with no gap Gc between adjacent reflection blocks among the reflection blocks 20c1 to 20c10. All of the reflection blocks 20c1 to 20c10 may have the arc shape with the same arc length, or at least one of the reflection blocks 20c1 to 20c10 may have an arc shape with a different arc length. The number of reflection blocks included in the reflector 20 is not limited to ten, and may be nine or less or eleven or more.

As illustrated in FIGS. 10D and 10E, the reflector 20 may have a configuration in which any one or more reflection blocks are removed from the ten reflection blocks 20c1 to 20c10 illustrated in FIG. 10C. In the example of FIG. 10D, the reflector 20 includes five reflection blocks 20c1, 20c3, 20c5, 20c7, and 20c9 formed by removing every other reflection block from the reflection blocks 20c1 to 20c10. In the example of FIG. 10E, the reflector 20 includes five reflection blocks 20c3, 20c4, 20c7, 20c8, and 20c9 formed by removing the reflection blocks 20c1, 20c2, 20c5, 20c6, and 20c10 from the reflection blocks 20c1 to 20c10. The number of reflection blocks removed from the ten reflection blocks 20c1 to 20c10 may be four or less, or six or more.

As illustrated FIG. 10F, the reflector 20 may include ten reflection blocks 20f1 to 20f10 each having a rectangular shape in the plan view. The reflection blocks 20f1 to 20f10 are arranged along the circumferential direction of the rotary table 400. The reflection blocks 20f1 to 20f10 are provided with a gap Gf between adjacent reflection blocks among the reflection blocks 20f1 to 20f10. However, the reflection blocks 20f1 to 20f10 may be provided with no gap Gf between adjacent reflection blocks among the reflection blocks 20f1 to 20f10. The number of reflection blocks included in the reflector 20 is not limited to ten, and may be nine or less, or eleven or more. Further, the reflector 20 may have a configuration in which any one or more reflection blocks are removed from the ten reflection blocks 20f1 to 20f10.

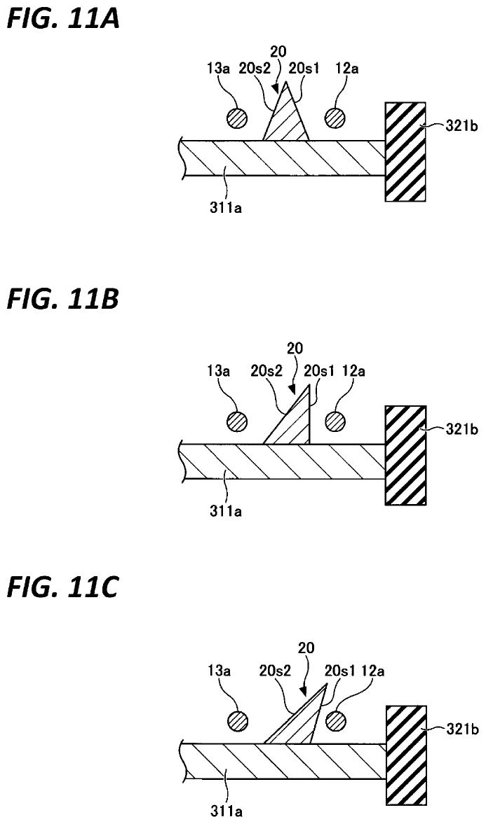

Next, the cross-sectional shape of the reflector 20 will be described with reference to FIGS. 11A to 11C through 15A to 15C. FIGS. 11A to 11C through 15A to 15C illustrate the cross section of the reflector 20 along the radial direction of the rotary table 400.

As illustrated in FIGS. 11A to 11C, the reflector 20 may have a triangular shape in the cross section along the radial direction of the rotary table 400. The reflector 20 includes a first surface 20s1 and a second surface 20s2. The first surface 20s1 is positioned to face the rotation shaft 321b, and the second surface 20s2 is positioned on the opposite side to the rotation shaft 321b.

In the example of FIG. 11A, the first surface 20s1 is inclined upward from below to be away from the rotation shaft 321b, and the second surface 20s2 is inclined upward from below to approach the rotation shaft 321b.

In the example of FIG. 11B, the first surface 20s1 extends vertically without being inclined, and the second surface 20s2 is inclined upward from below to approach the rotation shaft 321b.

In the example of FIG. 11C, the first surface 20s1 and the second surface 20s2 are inclined upward from below to approach the rotation shaft 321b.

In this way, when the reflector 20 has the second surface 20s2 inclined upward from below to approach the rotation shaft 321b in the cross section along the radial direction of the rotary table 400, the heating light emitted from the heating element 13a of the outer heater 13 is suppressed from being blocked by the reflector 20.

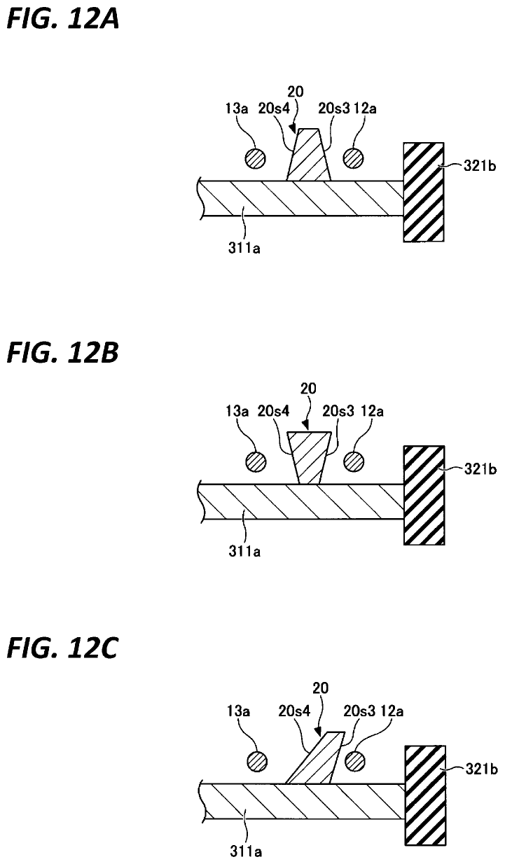

As illustrated in FIGS. 12A to 12C, the reflector 20 may have a trapezoidal shape in the cross section along the radial direction of the rotary table 400. The reflector 20 includes a first surface 20s3 and a second surface 20s4. The first surface 20s3 is positioned to face the rotation shaft 321b, and the second surface 20s4 is positioned on the opposite side to the rotation shaft 321b.

In the example of FIG. 12A, the first surface 20s3 is inclined upward from below to be away from the rotation shaft 321b, and the second surface 20s4 is inclined upward from below to approach the rotation shaft 321b.

In the example of FIG. 12B, the first surface 20s3 is inclined upward from below to approach the rotation shaft 321b, and the second surface 20s4 is inclined upward from below to be away from the rotation shaft 321b.

In the example of FIG. 12C, the first surface 20s3 and the second surface 20s4 are inclined upward from below to approach the rotation shaft 321b.

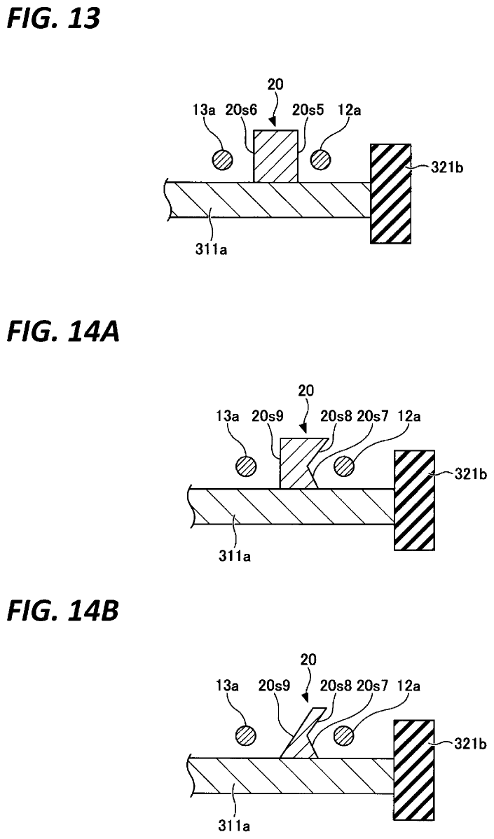

As illustrated in FIG. 13, the reflector 20 may have a rectangular shape in the cross section along the radial direction of the rotary table 400. The reflector 20 includes a first surface 20s5 and a second surface 20s6. The first surface 20s5 is positioned to face the rotation shaft 321b, and the second surface 20s6 is positioned on the opposite side to the rotation shaft 321b.

In the example of FIG. 13, the first surface 20s5 and the second surface 20s6 extend vertically without being inclined.

As illustrated in FIGS. 14A and 14B, the reflector 20 may have a polygonal shape in the cross section along the radial direction of the rotary table 400, such that the surface thereof facing the rotation shaft 321b surrounds the heating element 12a of the intermediate heater 12. In this case, the heating light emitted from the heating element 12a of the intermediate heater 12 may be efficiently reflected to the side of the rotation shaft 321b. The reflector 20 includes a first surface 20s7, a second surface 20s8, and a third surface 20s9. The first surface 20s7 and the second surface 20s8 are positioned to face the rotation shaft 321b, and the third surface 20s9 is positioned on the opposite side to the rotation shaft 321b. The boundary between the first surface 20s7 and the second surface 20s8 is positioned at substantially the same height as that of the heating element 12a of the intermediate heater 12.

In the example of FIG. 14A, the first surface 20s7 is inclined upward from below to be away from the rotation shaft 321b, and the second surface 20s8 is inclined upward from below to approach the rotation shaft 321b. The third surface 20s9 extends vertically without being inclined.

In the example of FIG. 14B, the first surface 20s7 is inclined upward from below to be away from the rotation shaft 321b, and the second surface 20s8 is inclined upward from below to approach the rotation shaft 321b. The third surface 20s9 is inclined upward from below to approach the rotation shaft 321b.

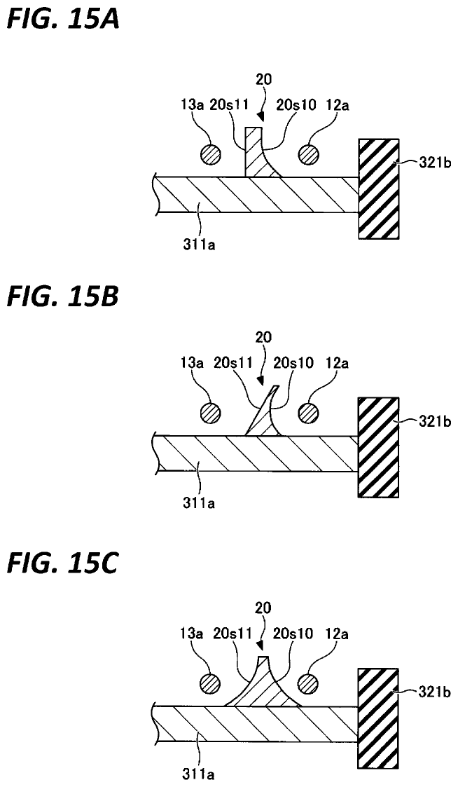

As illustrated in FIGS. 15A to 15C, the reflector 20 may have a curved surface that faces the rotation shaft 321b, in the cross section along the radial direction of the rotary table 400. In this case, it is possible to suppress the bias of the heating light emitted from the heating element 12a of the intermediate heater 12 and reflected on the surface of the reflector 20 that faces the rotation shaft 321b. By changing the curvature of the curved surface, the heating light reflected on the surface of the reflector 20 that faces the rotation shaft 321b may be made parallel light, or the focus of the heating light reflected on the surface of the reflector 20 that faces the rotation shaft 321b may be adjusted. The reflector 20 includes a first surface 20s10 and a second surface 20s11. The first surface 20s10 is positioned to face the rotation shaft 321b, and the second surface 20s11 is positioned on the opposite side to the rotation shaft 321b.

In the example of FIG. 15A, the first surface 20s10 is inclined upward from below to be away from the rotation shaft 321b, and the second surface 20s11 extends vertically without being inclined.

In the example of FIG. 15B, the first surface 20s10 is inclined in an arc shape such that the distance from the heating element 12a is constant regardless of a height position, and the second surface 20s11 is inclined upward from below to approach the rotation shaft 321b.

In the example of FIG. 15C, the first surface 20s10 is inclined upward from below in an arc shape to be away from the rotation shaft 321b, and the second surface 20s11 is inclined upward from below in an arc shape to approach the rotation shaft 321b.

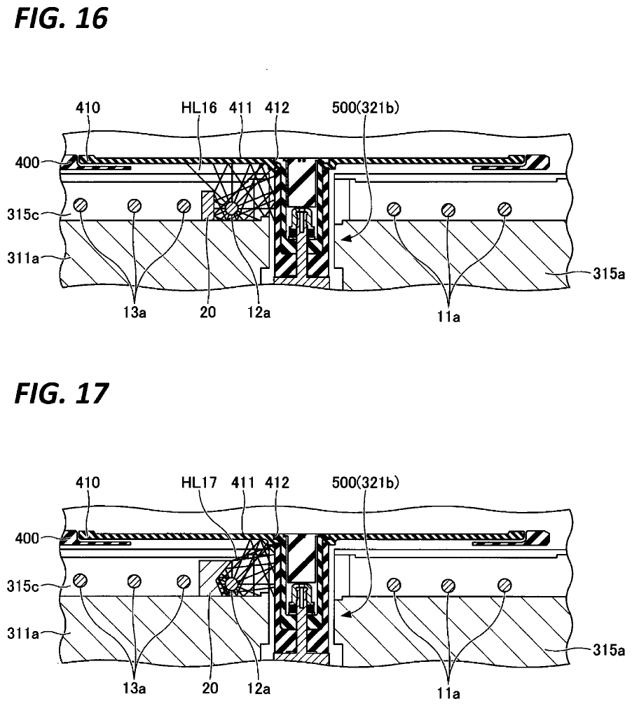

Next, with reference to FIGS. 16 to 18, effects of the deflector according to the example of the first configuration will be described. FIGS. 16 to 18 are views illustrating the directivity of the heating light emitted from the heating element of the heater 10.

FIG. 16 is a view illustrating an image of heating light HL16 emitted from the heating element 12a in a case where the reflector 20 having a rectangular cross section is provided between the heating element 12a of the intermediate heater 12 and the heating element 13a of the outer heater 13.

FIG. 17 is a view illustrating an image of heating light HL17 emitted from the heating element 12a in a case where the reflector 20 having a polygonal cross section that surrounds the heating element 12a is provided between the heating element 12a of the intermediate heater 12 and the heating element 13a of the outer heater 13.

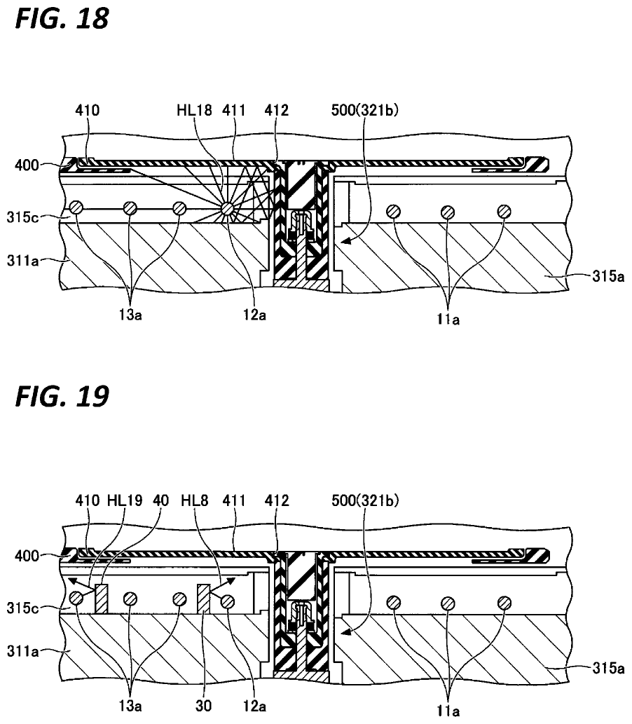

FIG. 18 is a view illustrating an image of heating light HL18 emitted from the heating element 12a in a case where the reflector 20 is not provided between the heating element 12a of the intermediate heater 12 and the heating element 13a of the outer heater 13.

As illustrated in FIG. 18, in a case where the reflector 20 is not provided, the heating light HL18 is emitted toward all directions from the heating element 13a. Meanwhile, when the reflector 20 is provided as illustrated in FIGS. 16 and 17, the heating lights HL16 and L17 emitted from the heating element 12a toward the outer periphery of the rotary table 400 are reflected toward the rotation shaft 321b by the reflector 20. Thus, the position of the rotation shaft 321b where the temperature hardly increases as compared with other regions may be selectively heated. As a result, the temperature uniformity in the in-plane of the substrate may be improved.

### Example of Second Configuration

With reference to FIG. 19, an example of a second configuration of the deflector provided in the above-described film forming apparatus 300 will be described. The deflector of the example of the second configuration includes a first reflector 30 that reflects the heating light emitted from the heating element of the heater 10 toward the rotation shaft 321b, and a second reflector 40 that reflects the heating light emitted from the heating element of the heater 10 toward the direction away from the rotation shaft 321b.

The first reflector 30 may have the same configuration as that of the reflector 20 described above.

The second reflector 40 is provided at a position farther from the rotation shaft 321b than the first reflector 30. The second reflector 40 reflects heating light HL19 emitted from the heating element 13a of the outer heater 13 provided at the position farther from the rotation shaft 321b than the second reflector 40, toward the direction away from the rotation shaft 321b. The second reflector 40 extends in the circumferential direction of the rotary table 400. The second reflector 40 may have the same material, installation structure, divided structure, and cross-sectional shape as those of the reflector 20 described above.

According to the deflector of the example of the second configuration, the heating light emitted from the heating element 12a of the intermediate heater 12 is reflected toward the rotation shaft 321b by the first reflector 30. As a result, the position of the rotation shaft 321b where the temperature hardly increases as compared with other regions may be selectively heated. As a result, the temperature uniformity in the in-plane of the substrate may be improved.

In the deflector of the example of the second configuration, the first reflector 30 is provided closer to the outer periphery of the rotary table 400 than the rotation shaft 321b. However, the present disclosure is not limited thereto. For example, the first reflector 30 may be provided closer to the rotation center Z1 of the rotary table 400 than the rotation shaft 321b. In this case, the first reflector 30 reflects the heating light emitted from the heating element 11a of the inner heater 11 toward the rotation shaft 321b. Further, the first reflector 30 may be provided on both sides closer to the outer periphery of the rotary table 400 than the rotation shaft 321b and closer to the rotation center Z1 of the rotary table 400 than the rotation shaft 321b, respectively.

### Example of Third Configuration

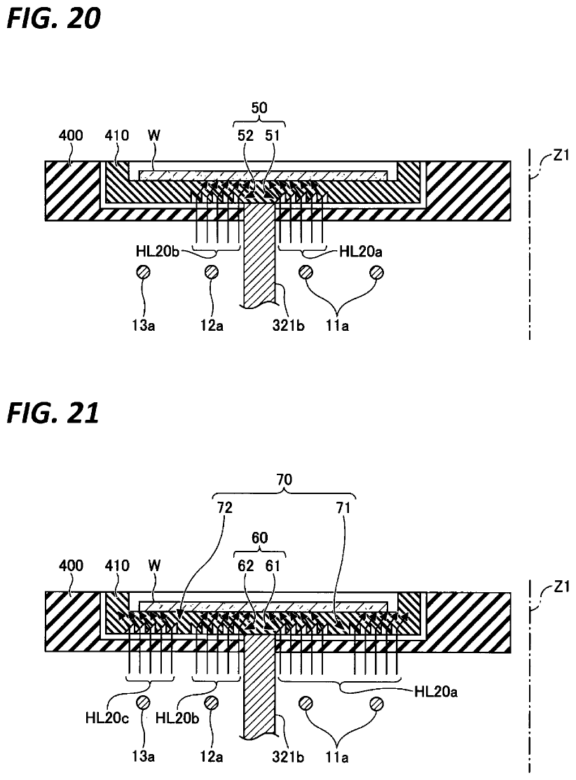

With reference to FIG. 20, an example of a third configuration of the deflector provided in the above-described film forming apparatus 300 will be described. The deflector of the example of the third configuration includes a condensing lens 50 that condenses the heating light emitted from the heating element of the heater 10 toward the rotation shaft 321b.

The condensing lens 50 is formed by processing the lower surface of the stage 410 into a Fresnel lens. The condensing lens 50 extends in the circumferential direction of the rotary table 400. The condensing lens 50 includes an inner condensing lens 51 and an outer condensing lens 52.

The inner condensing lens 51 is provided closer to the rotation center Z1 of the rotary table 400 than the rotation shaft 321b, and condenses heating light HL20a emitted from the heating element 11a of the inner heater 11 toward the rotation shaft 321b.

The outer condensing lens 52 is provided closer to the outer periphery of the rotary table 400 than the rotation shaft 321b, and condenses heating light HL20b emitted from the heating element 12a of the intermediate heater 12 toward the rotation shaft 321b.

According to the deflector of the example of the third configuration, the heating light HL20a emitted from the heating element 11a of the inner heater 11 is condensed toward the rotation shaft 321b by the inner condensing lens 51. Further, the heating light HL20b emitted from the heating element 12a of the intermediate heater 12 is condensed toward the rotation shaft 321b by the outer condensing lens 52. Thus, the position of the rotation shaft 321b where the temperature hardly increases as compared with other regions may be selectively heated. As a result, the temperature uniformity in the in-plane of the substrate may be improved.

In the deflector of the example of the third configuration, the condensing lens 50 includes the inner condensing lens 51 and the outer condensing lens 52. However, the present disclosure is not limited thereto. For example, the condensing lens 50 may be configured to include at least one of the inner condensing lens 51 and the outer condensing lens 52.

In the deflector of the example of the third configuration, the condensing lens 50 is formed by processing the lower surface of the stage 410 into a Fresnel lens. However, the present disclosure is not limited thereto. For example, the condensing lens 50 may be provided separately from the stage 410.

### Example of Fourth Configuration

With reference to FIG. 21, an example of a fourth configuration of the deflector provided in the above-described film forming apparatus 300 will be described. The deflector of the example of the fourth configuration includes a first condensing lens 60 that condenses the heating light emitted from the heating element of the heater 10 toward the rotation shaft 321b, and a second condensing lens 70 that condenses the heating light emitted from the heating element of the heater 10 toward the direction away from the rotation shaft 321b.

The first condensing lens 60 is formed by processing the lower surface of the stage 410 into a Fresnel lens. The first condensing lens 60 extends in the circumferential direction of the rotary table 400. The first condensing lens 60 includes an inner condensing lens 61 and an outer condensing lens 62. The inner condensing lens 61 and the outer condensing lens 62 may have the same configuration as that of the inner condensing lens 51 and the outer condensing lens 52 described above. That is, the inner condensing lens 61 condenses heating light HL20a emitted from the heating element 11a of the inner heater 11 toward the rotation shaft 321b. The outer condensing lens 62 condenses heating light HL20b emitted from the heating element 12a of the intermediate heater 12 toward the rotation shaft 321b.

The second condensing lens 70 is provided at a position farther from the rotation shaft 321b than the first condensing lens 60. The second condensing lens 70 is formed by processing the lower surface of the stage 410 into a Fresnel lens. The second condensing lens 70 extends in the circumferential direction of the rotary table 400. The second condensing lens 70 includes an inner condensing lens 71 and an outer condensing lens 72.

The inner condensing lens 71 condenses the heating light HL20a emitted from the heating element 11a of the inner heater 11 in the direction away from the rotation shaft 321b. The outer condensing lens 72 condenses heating light HL20c emitted from the heating element 13a of the outer heater 13 in the direction away from the rotation shaft 321b.

According to the deflector of the example of the fourth configuration, the heating light HL20a emitted from the heating element 11a of the inner heater 11 is condensed toward the rotation shaft 321b by the inner condensing lens 61. Further, the heating light HL20b emitted from the heating element 12a of the intermediate heater 12 is condensed toward the rotation shaft 321b by the outer condensing lens 62. Thus, the position of the rotation shaft 321b where the temperature hardly increases as compared with other regions may be selectively heated. As a result, the temperature uniformity in the in-plane of the substrate may be improved.

In the deflector according to the example of the fourth configuration, the first condensing lens 60 includes the inner condensing lens 61 and the outer condensing lens 62. However, the present disclosure is not limited thereto. For example, the first condensing lens 60 may be configured to include at least one of the inner condensing lens 61 and the outer condensing lens 62.

In the deflector of the example of the fourth configuration, the second condensing lens 70 includes the inner condensing lens 71 and the outer condensing lens 72. However, the present disclosure is not limited thereto. For example, the second condensing lens 70 may be configured to include at least one of the inner condensing lens 71 and the outer condensing lens 72.

In the deflector of the example of the fourth configuration, each of the first condensing lens 60 and the second condensing lens 70 is formed by processing the lower surface of the stage 410 into a Fresnel lens. However, the present disclosure is not limited thereto. For example, the first condensing lens 60 and the second condensing lens 70 may be provided separately from the stage 410.

### EXAMPLES

As for Examples, in the film forming apparatus 300 provided with the reflector 20 having the cross-sectional shape that surrounds the heating element as illustrated in FIG. 14A, the in-plane distribution of the substrate temperature when the substrate W on the stage 410 was heated was measured. In the Examples, the substrate W was heated under four Conditions A1 to A4.

In Condition A1, the set temperatures of all of the heaters (the inner heater 11, the intermediate heater 12, and the outer heater 13) were set to be the same.

In Condition A2, the set temperature of the inner heater 11 was set to be 10° C. higher than the set temperatures of the remaining heaters (the intermediate heater 12 and the outer heater 13).

In Condition A3, the set temperature of the intermediate heater 12 was set to be 20° C. higher than the set temperatures of the remaining heaters (the inner heater 11 and the outer heater 13).

In Condition A4, the set temperature of the outer heater 13 was set to be 20° C. higher than the set temperatures of the remaining heaters (the inner heater 11 and the intermediate heater 12).

The differences between the measurement results of Conditions A2 to A4 and the measurement result of Condition A1 were calculated, and the amount of temperature variation per set temperature of +1° C. was calculated. Subsequently, a normalization was performed for each of Conditions A2 to A4 such that the amount of temperature variation at the largest position became 1. By confirming the normalized values, it is possible to determine the position of the substrate W corresponding to the temperature variation to which each heater contributes. Specifically, it may be determined that a position having a relatively large normalized value is a position where the contribution to the temperature variation is relatively high.

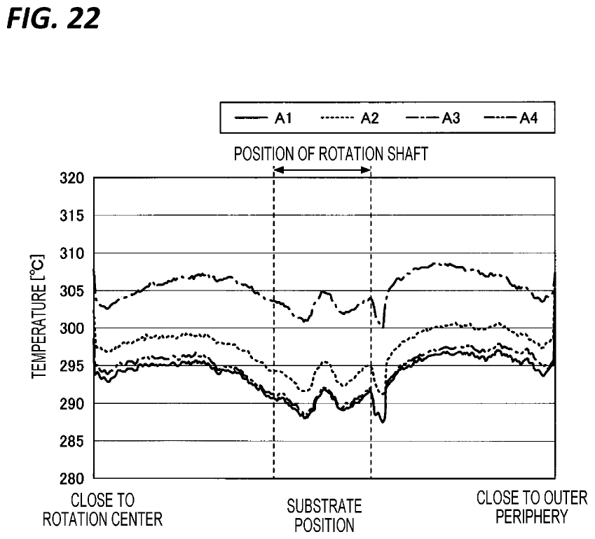

FIG. 22 is a view illustrating the measurement results of the in-plane distribution of the substrate temperature in the Examples. In FIG. 22, the horizontal axis represents the substrate position in the radial direction of the rotary table 400, and the vertical axis represents the temperature [° C.]. In FIG. 22, the solid line, the dashed line, the alternate long and short dash line, and the alternate long and two short dashes line represent the measurement results of the substrate temperature when the substrate W was heated under Conditions A1, A2, A3, and A4, respectively.

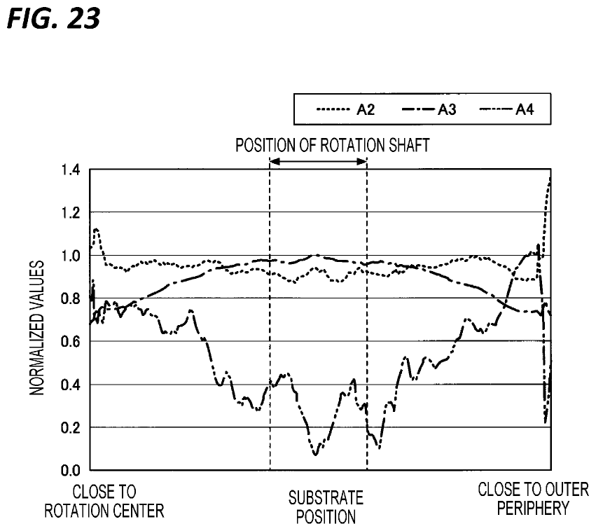

FIG. 23 is a graph obtained by normalizing the measurement results of FIG. 22. In FIG. 23, the horizontal axis represents the substrate position in the radial direction of the rotary table 400, and the vertical axis represents the normalized values of the measurement results of FIG. 22. In FIG. 23, the dashed line, the alternate long and short dash line, and the alternate long and two short dashes line represent the normalized values of the measurement results of the substrate temperature when the substrate W was heated under Conditions A2, A3, and A4, respectively.

As illustrated by the dashed line in FIG. 23, it may be confirmed that in Condition A2 in which the set temperature of the inner heater 11 is set to be 10° C. higher than the set temperatures of the intermediate heater 12 and the outer heater 13, the normalized values are roughly the same at any substrate positions. This result indicates that the contribution of the inner heater 11 to all of the substrate positions is substantially the same.

As illustrated by the alternate long and short dash line in FIG. 23, it may be confirmed that in Condition A3 in which the set temperature of the intermediate heater 12 is set to be 20° C. higher than the set temperatures of the inner heater 11 and the outer heater 13, the normalized values for the center of the substrate W (the position of the rotation shaft 321b) are larger than those for the peripheral edge of the substrate W. This result indicates that the contribution of the intermediate heater 12 to the center of the substrate W is higher than that to the peripheral edge of the substrate W.

As illustrated by the alternate long and two short dashes line in FIG. 23, it may be confirmed that in Condition A4 in which the set temperature of the outer heater 13 is set to be 20° C. higher than the set temperatures of the inner heater 11 and the intermediate heater 12, the normalized values for the peripheral edge of the substrate W are larger than those for the center of the substrate W. This result indicates that the contribution of the outer heater 13 to the peripheral edge of the substrate W is higher than that to the center of the substrate W.

Next, Comparative Examples performed for a comparison of the Examples will be described. For the Comparative Examples, in the film forming apparatus configured by removing the reflector 20 from the film forming apparatus 300 of the Examples, the in-plane distribution of the substrate temperature when the substrate W on the stage 410 was heated was measured. In the Comparative Examples, the substrate W was heated under the same four Conditions A1 to A4 as those in the Examples.

As in the Examples, the differences between the measurement results of Conditions A2 to A4 and the measurement result of Condition A1 were calculated, and the amount of temperature variation per set temperature of +1° C. was calculated. Subsequently, a normalization was performed for each of Conditions A2 to A4 such that the amount of temperature variation at the largest position became 1. By confirming the normalized values, it is possible to determine the position of the substrate W corresponding to the temperature variation to which each heater contributes. Specifically, it may be determined that a position having a relatively large normalized value is a position where the contribution to the temperature variation is relatively high.

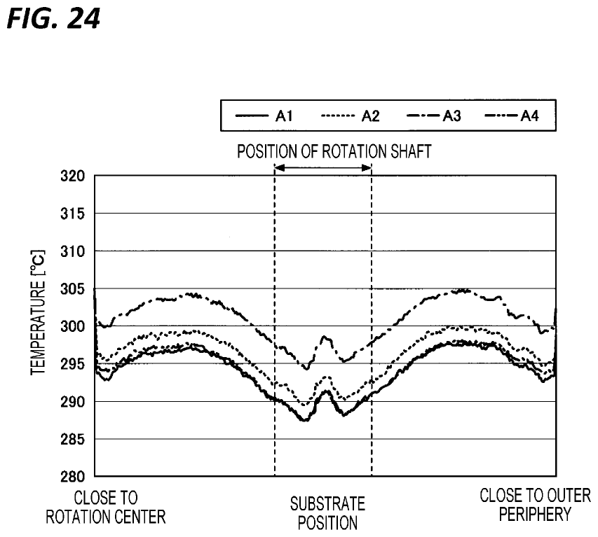

FIG. 24 is a view illustrating the measurement results of the in-plane distribution of the substrate temperature in the Comparative Examples. In FIG. 24, the horizontal axis represents the substrate position in the radial direction of the rotary table 400, and the vertical axis represents the temperature [° C.]. In FIG. 24, the solid line, the dashed line, the alternate long and short dash line, and the alternate long and two short dashes line indicate the measurement results of the substrate temperature when the substrate W was heated under Conditions A1, A2, A3, and A4, respectively.

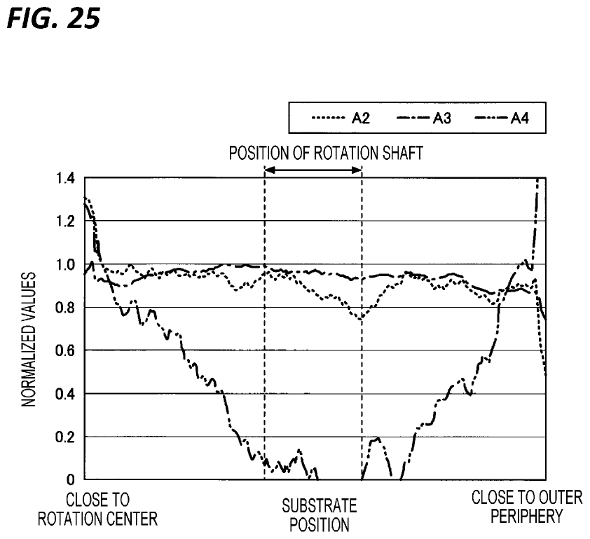

FIG. 25 is a graph obtained by normalizing the measurement results of FIG. 24. In FIG. 25, the horizontal axis represents the substrate position in the radial direction of the rotary table 400, and the vertical axis represents the normalized values of the measurement results of FIG. 24. In FIG. 25, the dashed line, the alternate long and short dash line, and the alternate long and two short dashes line indicate the normalized values of the measurement results of the substrate temperature when the substrate W was heated under Conditions A2, A3, and A4, respectively.

As illustrated by the dashed line in FIG. 25, it may be confirmed that in Condition A2 in which the set temperature of the inner heater 11 is set to be 10° C. higher than the set temperatures of the intermediate heater 12 and the outer heater 13, the normalized values are roughly the same at any substrate positions. This result indicates that the contribution of the inner heater 11 to all of the substrate positions is substantially the same.

As illustrated by the alternate long and short dash line in FIG. 25, it may be confirmed that in Condition A3 in which the set temperature of the intermediate heater 12 is set to be 20° C. higher than the set temperatures of the inner heater 11 and the outer heater 13, the normalized values are roughly the same at any substrate positions. This result indicates that the contribution of the intermediate heater 12 to all of the substrate positions is substantially the same.

As illustrated by the alternate long and two short dashes line in FIG. 25, it may be confirmed that in Condition A4 in which the set temperature of the outer heater 13 is set to be 20° C. higher than the set temperatures of the inner heater 11 and the intermediate heater 12, the normalized values for the peripheral edge of the substrate W are larger than those for the center of the substrate W. This result indicates that the contribution of the outer heater 13 to the peripheral edge of the substrate W is higher than that to the center of the substrate W.

From the results of the Examples and the Comparative Examples described above, it is believed that the center of the substrate W (the position of the rotation shaft 321b) may be selectively adjusted, by providing the reflector 20 between the intermediate heater 12 and the outer heater 13, and further, changing the set temperature of the intermediate heater 12. For example, it is believed that the center of the substrate W (the position of the rotation shaft 321b) may be selectively heated, by setting the set temperature of the intermediate heater 12 to be higher than the set temperatures of the remaining heaters. Thus, the position of the rotation shaft 321b where the temperature hardly increases as compared with other regions may be selectively heated. As a result, the temperature uniformity in the in-plane of the substrate may be improved.

According to the present disclosure, the temperature uniformity in the in-plane of the substrate may be improved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a rotary table provided in a processing container;
a stage provided on the rotary table to place a substrate thereon, and configured to revolve by a rotation of the rotary table;
a heater configured to heat the substrate placed on the stage; and
a rotation shaft configured to rotate together with the rotary table and support the stage to be rotatable; and
a deflector configured to deflect heating light emitted from the heater toward the rotation shaft.

2. The substrate processing apparatus according to claim 1, wherein the heater is provided around the rotation shaft.

3. The substrate processing apparatus according to claim 1, wherein the heater is provided along a circumferential direction of the rotary table below the rotary table.

4. The substrate processing apparatus according to claim 1, wherein the deflector includes a reflector that reflects the heating light emitted from the heater toward the rotation shaft.

5. The substrate processing apparatus according to claim 4, wherein the reflector extends in the circumferential direction of the rotary table along the heater.

6. The substrate processing apparatus according to claim 4, wherein the reflector has a shape in which a surface thereof facing the rotation shaft surrounds the heater, in a cross section taken along a radial direction of the rotary table.

7. The substrate processing apparatus according to claim 4, wherein the reflector includes a plurality of reflection blocks provided along a circumferential direction of the rotary table.

8. The substrate processing apparatus according to claim 4, wherein the reflector reflects the heating light emitted from the heater provided closer to the rotation shaft than the reflector, toward the rotation shaft.

9. The substrate processing apparatus according to claim 4, wherein the deflector includes a secondary reflector provided farther from the rotation shaft than the reflector, and
the secondary reflector reflects the heating light emitted from the heater provided farther from the rotation shaft than the secondary reflector, toward a direction away from the rotation shaft.

10. The substrate processing apparatus according to claim 1, wherein the deflector includes a condensing lens that condenses the heating light emitted from the heater toward the rotation shaft.

11. The substrate processing apparatus according to claim 10, wherein the condensing lens is formed by processing a lower surface of the stage into a Fresnel lens.

12. The substrate processing apparatus according to claim 10, wherein the deflector includes a secondary condensing lens provided farther from the rotation shaft than the condensing lens, and
the secondary condensing lens condenses the heating light emitted from the heater toward a direction away from the rotation shaft.
